(19) United States
(12) Patent Application Publication
(10) Pub. No.: US 2021/0280583 A1
(43) Pub. Date: Sep. 9, 2021

(54) SEMICONDUCTOR STRUCTURE AND FORMATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 17/249,542

(22) Filed: Mar. 4, 2021

(30) Foreign Application Priority Data
Mar. 5, 2020 (CN) 202010145752.2

(51) Int. Cl. H01L 27/092; H01L 29/78; H01L 29/10; H01L 21/8238

(52) U.S. Cl. CPC H01L 27/092; H01L 29/7827; H01L 21/823842; H01L 21/823885; H01L 29/1037

(57) ABSTRACT

A semiconductor structure and a fabrication method of the semiconductor structure are provided in the present disclosure. The semiconductor structure includes a substrate, including a first region, a second region, and a third region between the first region and the second region; a first channel pillar on the first region and a second channel pillar on the second region; a first work function layer on the first region of the substrate and on a sidewall surface of the first channel pillar; and a second work function layer on the second region of the substrate and on a sidewall surface of the second channel pillar.

### CROSS-REFERENCE TO RELATED APPLICATION

This application claims the priority of Chinese Patent Application No. 202010145752.2, filed on Mar. 5, 2020, the content of which is incorporated herein by reference in its entirety.

### TECHNICAL FIELD

The present disclosure generally relates to the field of semiconductor fabrication and, more particularly, relates to a semiconductor structure and its fabrication method.

### BACKGROUND

With continuous development of the semiconductor technology, the sizes of integrated circuit devices become smaller, and existing fin field-effect transistors have limitations in further increasing working current. For example, since only the area adjacent to the top surface and sidewalls of a fin is used as a channel region, the volume used as the channel region in the fin may be relatively small, which results in the limitation for increasing the working current in the fin field-effect transistor. Therefore, the field-effect transistor with a gate-all-around (GAA) structure is designed to increase the volume used as the channel region and further increase the working current of the fin field-effect transistor with the gate surrounding channel structure, thereby improving the performance of the semiconductor device.

However, there is a need to provide a semiconductor device with desirable device performance.

### SUMMARY

One aspect of the present disclosure provides a semiconductor structure. The semiconductor structure includes a substrate, including a first region, a second region, and a third region between the first region and the second region; a first channel pillar on the first region and a second channel pillar on the second region; a first work function layer on the first region of the substrate and on a sidewall surface of the first channel pillar; and a second work function layer on the second region of the substrate and on a sidewall surface of the second channel pillar.

Optionally, the structure further includes a first gate dielectric layer between the sidewall surface of the first channel pillar and the first work function layer, a second gate dielectric layer between the sidewall surface of the second channel pillar and the second work function layer, and a gate electrode layer on the first work function layer, the second work function layer, and the third region of the substrate.

Optionally, the substrate includes a first opening at the third region and exposed by a surface of the substrate; and a first dielectric layer is formed in the first opening and on the surface of the substrate.

Optionally, the first work function layer is made of a material including titanium aluminide.

Optionally, the second work function layer is made of a material including titanium nitride, tantalum nitride, or a combination thereof.

Optionally, a material of the first gate dielectric layer includes a combination of silicon oxide and a high dielectric constant material; and a material of the second gate dielectric layer includes a combination of silicon oxide and a high dielectric constant material.

Optionally, the substrate includes a first source/drain doped layer containing first ions and a second source/drain doped layer containing second ions; and conductivity types of the first ions and the second ions are different.

Another aspect of the present disclosure provides a method for fabricating a semiconductor structure. The method includes providing a substrate, including a first region, a second region, and a third region between the first region and the second region; forming a first channel pillar on the first region and a second channel pillar on the second region; forming a first work function layer on the first region of the substrate and on a sidewall surface of the first channel pillar; and forming a second work function layer on the second region of the substrate and on a sidewall surface of the second channel pillar.

Optionally, the method further includes forming a first gate dielectric layer between the sidewall surface of the first channel pillar and the first work function layer, forming a second gate dielectric layer between the sidewall surface of the second channel pillar and the second work function layer, and forming a gate electrode layer on the first work function layer, the second work function layer, and the third region of the substrate.

Optionally, forming the first gate dielectric layer and the first work function layer includes forming a first initial gate dielectric layer on the first channel pillar, and forming a first initial work function layer on the first initial gate dielectric layer, on the first region of the substrate, and on a portion of the third region; and forming the second gate dielectric layer and the second work function layer includes forming a second initial gate dielectric layer on the second channel pillar; and forming a second initial work function layer on the second initial gate dielectric layer, on the second region of the substrate, and on a portion of the third region.

Optionally, forming the second initial work function layer includes forming a second initial work function material layer on the substrate, the first initial gate dielectric layer, and the second initial gate dielectric layer; forming a second patterned layer on the second initial work function material layer at the second region and the portion of the third region; and using the second patterned layer as a mask, etching the second initial work function material layer.

Optionally, forming the first initial work function layer includes forming a first initial work function material layer on the substrate, the first initial gate dielectric layer, and the second initial work function layer.

Optionally, forming the first initial work function layer further includes forming a first patterned layer on the first initial work function material layer at the first region and the portion of the third region; and using the first patterned layer as a mask, etching the first initial work function material layer till a surface of the second initial work function layer is exposed.

Optionally, forming the first work function layer and the second work function layer further includes removing the first initial work function layer and the second initial work function layer on the third region.

Optionally, removing the first initial work function layer and the second initial work function layer on the third region of the substrate includes forming a first sidewall spacer on the first initial work function layer on the sidewall surface of the first channel pillar and on a portion of the first region of the substrate; forming a second sidewall spacer on the second initial work function layer on the sidewall surface of the second channel pillar and on a portion of the second region of the substrate; and using the first sidewall spacer and the second sidewall spacer as a mask, etching the first initial work function layer and the second initial work function layer till the first initial work function layer and the second initial work function layer on the third region are removed.

Optionally, forming the first sidewall spacer and the second sidewall spacer includes depositing a sidewall spacer material layer on the first initial work function layer and the second initial work function layer; and etching back the sidewall spacer material layer till surfaces of the first initial work function layer and the second initial work function layer are exposed.

Optionally, forming the gate electrode layer includes after removing the first initial work function layer and the second initial work function layer on the third region, forming a gate electrode material layer on the first channel pillar, the second channel pillar, and the substrate; and etching the gate electrode material layer on tops of the first channel pillar and the second channel pillar to form the gate electrode layer.

Optionally, forming the first gate dielectric layer and the second gate dielectric layer includes after etching the gate electrode material layer on the tops of the first channel pillar and the second channel pillar, etching an exposed first initial gate dielectric layer and an exposed second initial gate dielectric layer.

Optionally, after forming the first channel pillar and the second channel pillar and before forming the first work function layer and the second work function, the method further includes forming a first opening at the third region of the substrate and exposed by a surface of the substrate; and forming a first dielectric layer in the first opening and on the surface of the substrate.

Compared with the existing technology, the technical solutions provided by the present disclosure may achieve at least the following beneficial effects.

In the semiconductor structure provided by the technical solutions of the present disclosure, the substrate includes the first region, the second region, and the third region between the first region and the second region; the first work function layer is on the sidewall surface of the first channel pillar and the first region, and the second work function layer is on the sidewall surface of the second channel pillar and the second region. That is, the first work function layer and the second work function layer are separated from each other. Therefore, the ion diffusion between the first work function layer and the second work function layer may be reduced, thereby reducing the ion concentration change in the first work function layer and the second work function layer. Furthermore, the change of the turn-on voltage of the semiconductor device may be reduced, and the deviation of the electrical performance of the semiconductor device may be reduced, such that the stability of the electrical performance of the semiconductor device may be improved, thereby improving the performance of the semiconductor device.

Correspondingly, in the method for fabricating the semiconductor structure provided by the technical solutions of the present disclosure, the substrate includes the first region, the second region, and the third region between the first region and the second region; the first work function layer is formed on the sidewall surface of the first channel pillar and the first region, and the second work function layer is formed on the sidewall surface of the second channel pillar and the second region. That is, the first work function layer and the second work function layer are separated from each other. Therefore, after forming the first work function layer and the second work function layer, the ion diffusion between the first work function layer and the second work function layer due to high temperature may be reduced when the temperature of the subsequent fabrication process is relatively high, thereby reducing the ion concentration change in the first work function layer and the second work function layer. Furthermore, the change of the turn-on voltage of the semiconductor device may be reduced, and the deviation of the electrical performance of the semiconductor device may be reduced, such that the stability of the electrical performance of the semiconductor device may be improved, thereby improving the performance of the semiconductor device.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional structural schematic of a complementary metal-oxide-semiconductor (CMOS) device;

FIGS. 2-12 illustrate cross-sectional structural schematics corresponding to certain stages of a method for fabricating an exemplary semiconductor structure according to various disclosed embodiments of the present disclosure; and

FIG. 13 illustrates a flowchart of an exemplary method for fabricating a semiconductor structure according to various disclosed embodiments of the present disclosure.

### DETAILED DESCRIPTION

Reference may now be made in detail to exemplary embodiments of the disclosure, which are illustrated in the accompanying drawings. Wherever possible, the same reference numbers may be used throughout the drawings to refer to the same or like parts.

A semiconductor structure and a fabrication method of the semiconductor structure are provided in the present disclosure. The semiconductor structure includes a substrate, including a first region, a second region, and a third region between the first region and the second region; a first channel pillar on the first region and a second channel pillar on the second region; a first work function layer on the first region of the substrate and on a sidewall surface of the first channel pillar; and a second work function layer on the second region of the substrate and on a sidewall surface of the second channel pillar.

FIG. 1 illustrates a cross-sectional structural schematic of a complementary metal-oxide-semiconductor (CMOS) device.

Referring to FIG. 1, The CMOS device may include a substrate including a first region I and a second region II, where a first base substrate 11 which is a P-type silicon substrate may be at the first region I, and a second base substrate 12 which is a N-type silicon substrate may be at the second region II; a first source/drain doped layer 20 on the surface of a portion of the first substrate 11, where the first source/drain doped layer 20 may be doped with N-type ions; a second source/drain doped layer 30 on the surface of a portion of the second substrate 12, where the second source/drain doped layer 30 may be doped with P-type ions; a first channel pillar 40 on the surface of a portion of the first source/drain doped layer 20; a second channel pillar 50 on the surface of a portion of the second source/drain doped layer 30; a first dielectric layer 60 on the surfaces of the first source/drain doped layer 20 and the second source/drain doped layer 30, between the first source/drain doped layer 20 and the second source/drain doped layer 30, and between the first base substrate 11 and the second base substrate 12; a first gate structure on a portion of the sidewall surface of the first channel pillar 40 and the surface of a portion of the first dielectric layer 60 at the first region I; and a second gate structure on a portion of the sidewall surface of the second channel pillar 50 and the surface of a portion of the first dielectric layer 60 at the second region II.

For example, the first gate structure may include a first gate dielectric layer 71 on the portion of the sidewall surface of the first channel pillar 40, and include a first work function layer 72, where the first work function layer 72 may be on the surface of the first gate dielectric layer 71 and the surface of the portion of the first dielectric layer 60 at the first region I.

The second gate structure may include a second gate dielectric layer 73 on the portion of the sidewall surface of the second channel pillar 50, and include a second work function layer 74, where the second work function layer 74 may be on the surface of the second gate dielectric layer 73 and the surface of the portion of the first dielectric layer 60 at the second region II.

The material of the first work function layer 72 may include titanium aluminide.

The material of the second work function layer 74 may include titanium nitride.

The first gate structure and the second gate structure may further include a shared gate electrode layer 70. The gate electrode layer 70 may be on the surface of the first function layer 72, the surface of the second function layer 74, the surface of a portion of the dielectric layer 60 at the first region I, and the surface of a portion of the dielectric layer 60 at the second region II.

In the above-mentioned embodiment, the field-effect transistor with a gate-all-around (GAA) structure may increase the volume used as the channel region and further increase the working current of the fin field-effect transistor with the gate surrounding channel structure, thereby improving the performance of the semiconductor device.

However, the first work function layer 72 and the second work function layer 74 are connected with each other in the above-mentioned structure of the CMOS device, so that the aluminum ions in the first work function layer 72 may easily be heated to diffuse into the second work function layer 74 when the CMOS device is heated during the usage or used to form other devices subsequently. Therefore, the aluminum ion concentration in the first work function layer 72 may be decreased, thereby increasing the turn-on voltage of the first gate structure; and the aluminum ion concentration in the second work function layer 74 may be increased, thereby increasing the turn-on voltage of the first gate structure. As a result, the electrical performance of the CMOS device may be deviated, that is, the stability of the electrical performance of the CMOS device may be poor, which may cause the poor performance of the CMOS device.

In order to solve the above-mentioned technical problem, the embodiments of the present disclosure provide a semiconductor structure. The semiconductor structure may include a substrate, where the substrate includes a first region, a second region, and a third region between the first region and the second region; a first channel pillar on the surface of the first region and a second channel pillar on the surface of the second region; a first work function on the first region of the substrate and the sidewall surface of the first channel pillar; and a second work function on the second region of the substrate and the sidewall surface of the second channel pillar, which may improve the performance of the semiconductor structure.

In order to clearly illustrate the above-mentioned objectives, features, and advantages of the present disclosure, various embodiments of the present disclosure are described in detail with reference to the accompanying drawings hereinafter.

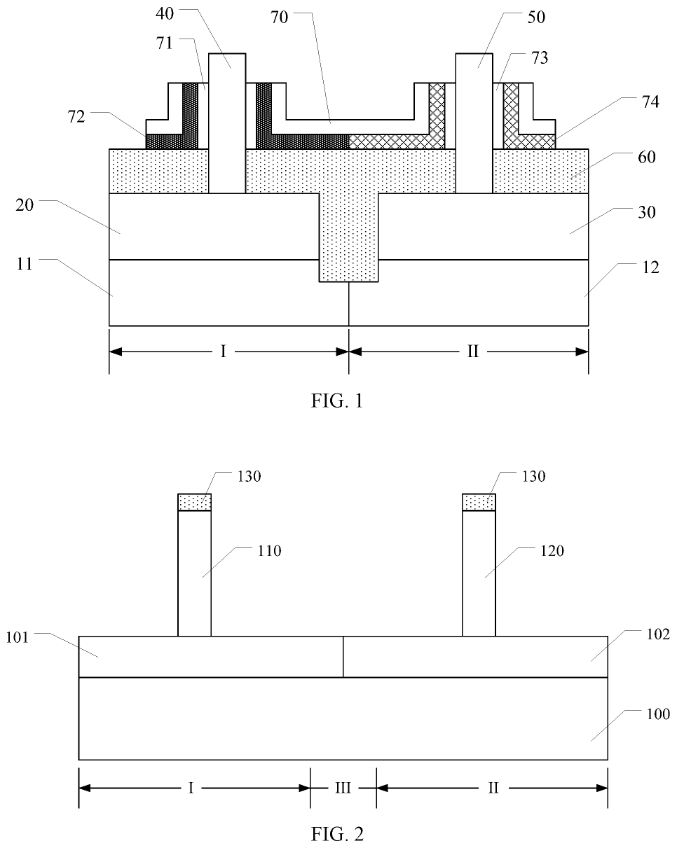

FIGS. 2-12 illustrate cross-sectional structural schematics corresponding to certain stages of a method for fabricating an exemplary semiconductor structure according to various disclosed embodiments of the present disclosure.

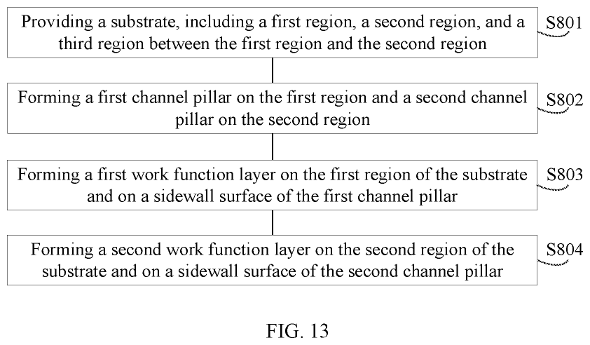

Referring to FIG. 2, a substrate 100 may be provided; the substrate 100 may include a first region I, a second region II, and a third region III between the first region I and the second region II (e.g., in S801 of FIG. 13); and a first channel pillar 110 may be formed on the surface of the first region I, and a second channel pillar 120 may be formed on the surface of the second region II (e.g., in S802 of FIG. 13).

The substrate 100 may be made of a semiconductor material.

In one embodiment, the substrate 100 may be made of silicon. In other embodiments, the substrate may be made of a material including silicon carbide, silicon germanium, a multi-element semiconductor material composed of group III-V elements, silicon-on-insulator (SOI), germanium-on-insulator, and/or any combination thereof. The multi-element semiconductor material composed of group III-V elements may include InP, GaAs, GaP, InAs, InSb, InGaAs, InGaAsP, and/or a combination thereof.

In one embodiment, the substrate 100 may include a first initial source/drain doped layer 101, which is at the first region I and a portion of the third region III and include a second initial source/drain doped layer 102, which is at the second region II and a portion of the third region III.

The first initial source/drain doped layer 101 may contain first ions, the second initial source/drain doped layer 102 may contain second ions, and the conductivity types of the first ions and the second ions may be different from each other.

The first initial source/drain doped layer 101 may be used to subsequently form a first source/drain doped layer in the first region I; and the second initial source/drain doped layer 102 may be used to subsequently form a second source/drain doped layer in the second region II.

For example, in one embodiment, the surface of the substrate 100 at the first region I may include the surface of the first source/drain doped layer, and the surface of the substrate 100 at the second region II may include the surface of the second source/drain doped layer.

In one embodiment, the first ions may be N-type, and the second ions may be P-type. Therefore, an N-type device may be formed in the first region I, and a P-type device may be formed in the second region II, subsequently, thereby forming the CMOS device in the semiconductor structure.

In other embodiments, the first ions may be P-type, and the second ions may be N-type.

The N-type ions may include phosphorus ions, arsenic ions, or antimony ions, and the P-type ions may include boron ions, BF²⁻ ions, or indium ions.

In one embodiment, the first initial source/drain doped layer 101 and the second initial source/drain doped layer 102 may be formed by a process including an epitaxial growth process.

In one embodiment, forming the first channel pillar 110 and the second channel pillar 120 may include forming a channel pillar material layer (not shown) on the surface of the substrate 100; forming a third patterned layer 130 on a portion of the surface of the channel pillar material layer at the first region I and a portion of the channel pillar material layer at the second region II; and using the third patterned layer 130 as a mask, etching the channel pillar material layer till exposing the surface of the substrate 100.

In one embodiment, the third patterned layer 130 may be made of silicon nitride.

In other embodiments, the third patterned layer 130 may be made of a material including silicon oxide, silicon oxynitride, silicon oxycarbide, silicon carbonitride, silicon oxycarbonitride, and/or any suitable material(s).

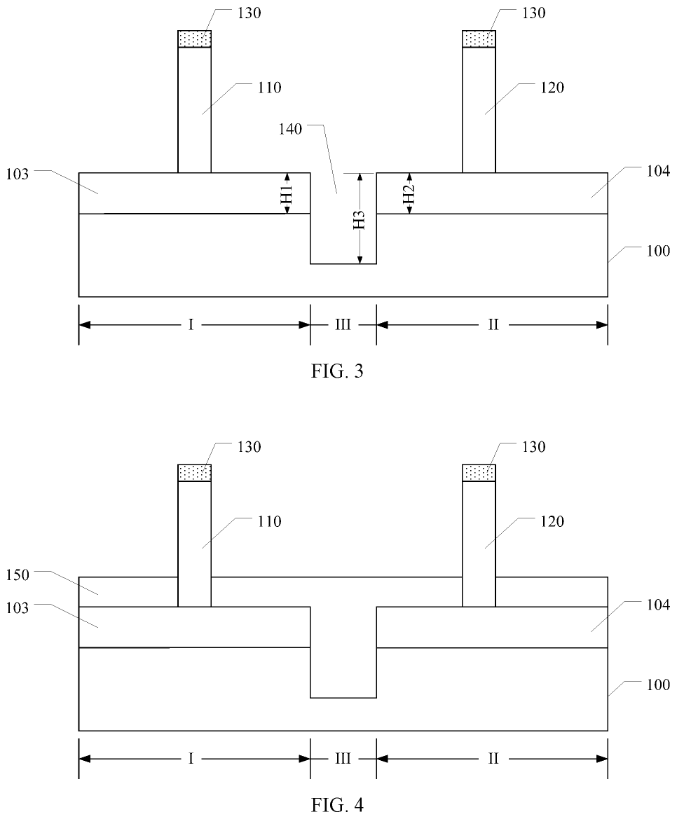

In one embodiment, after forming the first channel pillar 110 and the second channel pillar 120 and before subsequently forming the first work function layer and the second work function layer, a first opening may be formed in the third region III, and the surface of the substrate 100 may expose the first opening. Furthermore, referring to FIGS. 3-4, a first dielectric layer may be formed in the first opening and on the surface of the substrate 100.

Referring to FIG. 3, after forming the first channel pillar 110 and the second channel pillar 120, a first opening 140 may be formed in the third region III; and the surface of the substrate 100 may expose the first opening 140.

In one embodiment, along the direction perpendicular to the surface of the substrate 100, the first initial source/drain doped layer 101 may have a first thickness H1, and the second initial source/drain doped layer 102 may have a second thickness H2, and the distance between the bottom surface of the first opening 140 and the top surface of the substrate 100 may be a third spacing H3. Moreover, the third spacing H3 may be greater than each of the first thickness H1 and the second thickness H2. Therefore, while forming the first opening 140, the first initial source/drain doped layer 101 and the second initial source/drain doped layer 102 in the third region III may be removed.

Therefore, on the one hand, the first source/drain doped layer 103 in the first region I may be formed by removing the first initial source/drain doped layer 101 in the third region III, and the second source/drain doped layer 104 in the second region II may be formed by removing the second initial source/drain doped layer 102 in the third region III; on the other hand, the first opening 140 may also provide space for the subsequent formation of the first dielectric layer.

The first source/drain doped layer 103 is formed using the first initial source/drain doped layer 101 as the material, and the second source/drain doped layer 104 is formed using the second initial source/drain doped layer 102 as the material. Therefore, the first source/drain doped layer 103 may contain first ions, the second source/drain doped layer 104 may contain second ions, and the conductivity types of the first ions and the second ions may be different from each other.

In one embodiment, forming the first opening 140 may include forming a fourth patterned layer on the first channel pillar 110, the second channel pillar 120, and the substrate 100 (not shown), where the fourth patterned layer exposes the surface of the third region III; and using the fourth patterned layer as a mask, etching the substrate 100 at the third region III till the first opening 140 is formed.

The substrate 100 at the third region III may be etched by a process including a dry etching process, a wet etching process, or a combination thereof.

In one embodiment, the substrate 100 at the third region III may be etched by a dry etching process. The process parameters of the dry etching process may include gases including CF₄, O₂, CH₃F and He, where the flow range of CF₄ is from about 10 standard mL/min to about 400 standard mL/min, the flow range of 02 is from about 8 standard mL/min to about 200 standard mL/min, the flow range of CH₃F is from about 40 standard mL/min to about 900 standard mL/min, the flow range of He is from about 6 standard mL/min to about 300 standard mL/min, and the pressure range is from about 5 mTorr to about 300 mTorr.

Referring to FIG. 4, a first dielectric layer 150 may be formed in the first opening 140 and on the surface of the substrate 100.

On the one hand, the first dielectric layer 150 in the first opening 140 may reduce the current crosstalk between the first region I and the second region II, thereby improving the performance of the semiconductor device; on the other hand, the first dielectric layer on the surface of the substrate 100 may insulate the first channel pillar 110 from the second channel pillar 120, and insulate the first work function layer, the second work function layer and the gate electrode layer, which are subsequently formed, from the substrates 100, thereby forming the CMOS device in the semiconductor structure.

In one embodiment, forming the first dielectric layer 150 may include forming a first dielectric material layer (not shown) in the first opening 140 and on the surface of the substrate 100; and etching back the first dielectric material layer till the first dielectric layer 150 is formed.

By etching-back the first dielectric material layer, it is easier to control the overall thickness of the first dielectric layer 150 along the direction perpendicular to the substrate surface 100, thereby forming the first dielectric layer 150 with higher accuracy.

In another embodiment, the first dielectric layer may be formed directly in the first opening 140 and on the surface of the substrate 100. Therefore, steps and time of the semiconductor fabrication process may be reduced.

The first dielectric material layer may be formed by a process including a deposition process.

In one embodiment, the deposition process may be an atomic layer deposition process.

In other embodiments, the deposition process may include a chemical vapor deposition process.

The first dielectric material layer may be etched back by a process including a dry etching process, a wet etching process, or a combination thereof.

In one embodiment, the first dielectric material layer may be etched back by a wet etching process.

In one embodiment, the first dielectric layer 150 may be made of silicon oxide.

In one embodiment, the first work function layer may be subsequently formed on the sidewall surface of the first channel pillar 110 and on the first region I; and the second work function layer may be formed on the sidewall surface of the second channel pillar 120 and on the second region II.

The substrate 100 includes the first region I, the second region II, and the third region III between the first region I and the second region II; the first work function layer is formed on the sidewall surface of the first channel pillar 110 and on the first region I, and the second work function layer is formed on the sidewall surface of the second channel pillar 120 and on the second region II, that is, the first work function layer and the second work function layer are separated from each other. Therefore, after forming the first work function layer and the second work function layer, the ion diffusion between the first work function layer and the second work function layer due to high temperature may be reduced when the temperature of the subsequent fabrication process is relatively high, thereby reducing the ion concentration change in the first work function layer and the second work function layer. Furthermore, the change of the turn-on voltage of the semiconductor device may be reduced, and the deviation of the electrical performance of the semiconductor device may be reduced, such that the stability of the electrical performance of the semiconductor device may be improved, thereby improving the performance of the semiconductor device.

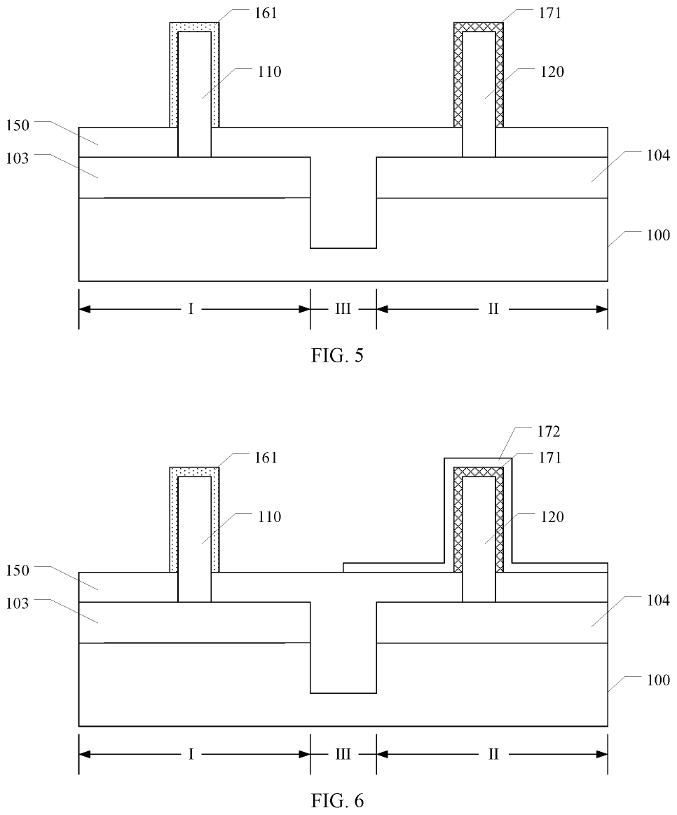

In one embodiment, the first gate dielectric layer may be subsequently formed between the sidewall surface of the first channel pillar 110 and the first work function layer, and the second gate dielectric layer may be formed on the sidewall surface of the second channel pillar 120 and the second work function layer. The gate electrode layer may be formed on the surface of the first work function layer, the surface of the second work function layer and the surface of the third region. Forming the first work function layer, the second work function layer, the first gate dielectric layer, the second gate dielectric layer, and the gate electrode layer may refer to FIGS. 5-11 for details.

Referring to FIG. 5, a first initial gate dielectric layer 161 may be formed on the surface of the first channel pillar 110, and a second initial gate dielectric layer 171 may be formed on the surface of the second channel pillar 120.

The first initial gate dielectric layer 161 may be used to subsequently form the first gate dielectric layer, and the second gate dielectric layer 171 may be used to subsequently form the second gate dielectric layer.

In one embodiment, the first initial gate dielectric layer 161 may be formed by a process including a thermal oxidation process.

In one embodiment, the second initial gate dielectric layer 171 may be formed by a process including a thermal oxidation process.

The process parameters of the thermal oxidation process may include an oxidation temperature range of about 850 degrees Celsius to about 1050 degrees Celsius, a pressure range of about 0.1 standard atmosphere to about 1 standard atmosphere, a reaction gas including 02 or H₂O, and a carrier gas including Na, where the flow ratio between 02 and Na is about 1:5, and the flow ratio between H₂O and Na is about 1:100.

In one embodiment, the material of the first initial gate dielectric layer 161 may include a combination of silicon oxide and a high dielectric constant material.

Therefore, silicon oxide may provide a desirable interface state between the first initial gate dielectric layer 161 and the first channel pillar 110; and the high dielectric constant material may make the first initial gate dielectric layer 161 have a desirable insulation performance (higher dielectric constant).

In other embodiments, the material of the first initial gate dielectric layer 161 may include silicon oxide.

In one embodiment, the material of the second initial gate dielectric layer 171 may include a combination of silicon oxide and a high dielectric constant material.

Therefore, silicon oxide may provide a desirable interface state between the second initial gate dielectric layer 171 and the second channel pillar 120; and the high dielectric constant material may make the first initial gate dielectric layer 161 have a desirable insulation performance (higher dielectric constant).

In other embodiments, the material of the second initial gate dielectric layer 171 may include silicon oxide.

It should be noted that the high dielectric constant material may be a material with a dielectric constant greater than 3.9.

The high dielectric constant material may include titanium oxide, aluminum oxide, hafnium oxide, tantalum oxide, lanthanum oxide, and/or any other suitable material(s).

In one embodiment, the high dielectric constant material may include hafnium oxide.

In one embodiment, before forming the first initial gate dielectric layer 161 and the second initial gate dielectric layer 171, the third patterned layer 130 may be removed.

Referring to FIG. 6, a second initial work function layer 172 may be formed on the surface of the second initial gate dielectric layer 171, on the second region II, and on a portion of the third region III.

In one embodiment, forming the second initial work function layer 172 may include forming a second initial work function material layer (not shown) on the substrate 100, the surface of the first initial gate dielectric layer 161 and the surface of the second initial gate dielectric layer 171; forming a second patterned layer (not shown) on the surface of the second initial work function material layer at the second region II and a portion of the third region III; and using the second patterned layer as a mask, etching the second initial work function material layer till the surface of the first dielectric layer 150 is exposed.

In one embodiment, the material of the second initial work function layer 172 may include titanium nitride or tantalum nitride.

In another embodiment, the material of the second initial work function layer may include titanium aluminide.

The second initial work function material layer may be formed by a process including a deposition process.

In one embodiment, the deposition process may be an atomic layer deposition process. The process parameters of the atomic layer deposition process may include a reactive gas including a precursor containing nitrogen and titanium, a temperature range of about 200 degrees Celsius to about 650 degrees Celsius, and a pressure range of about 1 mTorr to about 200 mTorr.

In other embodiments, the deposition process may include a chemical vapor deposition process.

The second initial work function material layer may be etched by a process including a dry etching process, a wet etching process, and/or a combination thereof.

In one embodiment, the second initial work function material layer may be etched by a dry etching process. The process parameters of the dry etching process may include gases including SF₆ and Cl₂, where the flow range of SF₆ is about 20 standard mL/min to about 300 standard mL/min, and the flow range of Cl₂ is about 60 standard mL/min to about 150 standard mL/min; and further include a pressure range about 2 mTorr to about 200 mTorr.

In one embodiment, after the second initial work function layer 172 is formed, the second patterned layer may be removed.

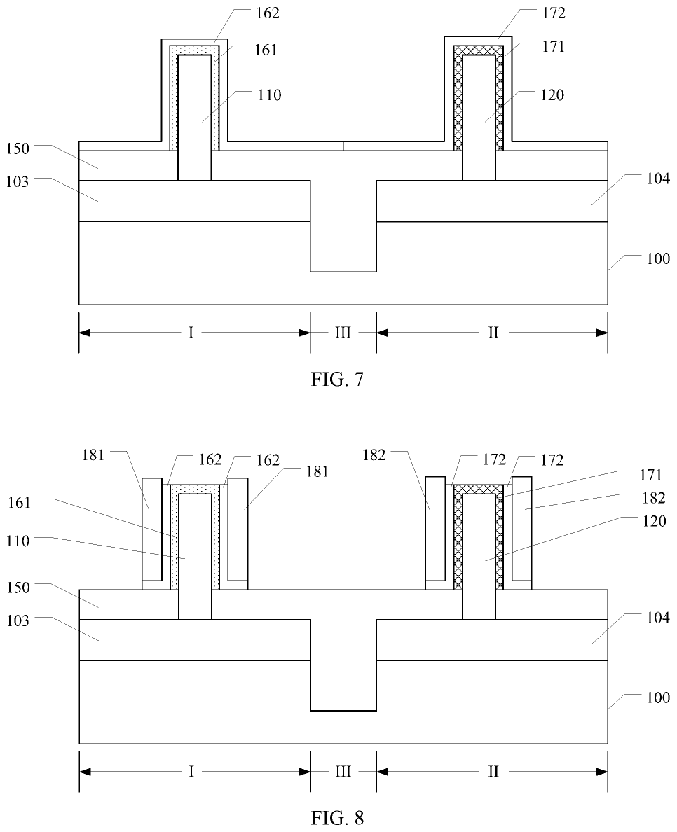

Referring to FIG. 7, a first initial work function layer 162 may be formed on the surface of the first initial gate dielectric layer 161, on the first region I, and on a portion of the third region III.

In one embodiment, forming the first initial work function layer 162 may include forming a first initial work function material layer (not shown) on the substrate 100, on the surface of the first initial gate dielectric layer 161 and the surface of the second initial work function layer 172.

In one embodiment, forming the first initial work function layer 162 may further include forming a first patterned layer (not shown) on the surface of the first initial work function material layer at the first region I and a portion of the third region II; and using the first patterned layer as a mask, etching the first initial work function material layer till the surface of the second initial work function layer 172 is exposed.

In another embodiment, the second initial work function layer may be formed after forming the first initial work function layer.

In another embodiment, along the direction perpendicular to the surface of the substrate, the second initial work function layer may include a fourth region, and a fifth region on the fourth region; before forming the first initial work function material layer, the second initial work function layer at the fifth region may be modified to form a fifth isolation region; and after the first initial work function material layer is formed, the first initial work function material layer may not be etched using the first patterned layer as a mask, that is, the first initial work function material layer at the second region may not be removed.

On the one hand, even if the first initial work function material layer at the second region is not removed, after the formation of the fifth isolation region, the ions of the first initial work function material layer or the second initial work function material layer diffusing through the top surface of the second initial work function layer may be reduced using the fifth isolation region when the temperature of the subsequent fabrication process is relatively high. Therefore, the change of ion concentration in the second work function layer formed subsequently may be reduced, and the change of the turn-on voltage of the semiconductor device may be reduced, that is, the deviation of the electrical performance of the semiconductor device may be reduced, thereby improving the stability of the electrical performance of the semiconductor device and the performance of the semiconductor device. On the other hand, due to the modification treatment of the fifth region, the modified portion of the second initial work function layer may be relatively small. Therefore, the modification treatment may have relatively minor effect on the electrical properties, such as the turn-on voltage, of the second work function layer formed subsequently.

In one embodiment, the material of the first initial work function layer 162 may include titanium aluminide.

In another embodiment, the material of the first initial work function layer may include titanium nitride or tantalum nitride.

The first initial work function material layer may be formed by a process including a deposition process.

In one embodiment, the deposition process may be an atomic layer deposition process. The process parameters of the atomic layer deposition process may include a reactive gas includes a precursor containing aluminum and titanium, a temperature range of about 250 degrees Celsius to about 650 degrees Celsius, and a pressure of about 5 mTorr to about 200 mTorr.

In other embodiments, the deposition process may include a chemical vapor deposition process.

The first initial work function material layer may be etched by a process including a dry etching process, a wet etching process, and/or a combination thereof.

In one embodiment, the first initial work function material layer may be etched by a dry etching process. The process parameters of the dry etching process may include gases including SF₆, Cl₂, and CF₄, where the flow range of SF₆ is about 30 standard mL/min to about 300 standard mL/min, the flow range of Cl₂ is about 60 standard mL/min to about 150 standard mL/min, and the flow range of CF₄ is about 10 standard mL/min to about 600 standard mL/min; and further include a pressure range of about 2 mtorr to about 200 mtorr.

In one embodiment, after the first initial work function layer 162 is formed, the second patterned layer may be removed.

Refer to FIG. 8, the first initial work function layer 162 and the second initial work function layer 172 on the third region III may be removed.

In one embodiment, removing the first initial work function layer 162 and the second initial work function layer 172 on the surface of the third region III may include forming first sidewall spacers 181 on the surface of the first initial work function layer 162 on the sidewall of the first channel pillar 110 and on a portion of the first region I; forming second sidewall spacers 182 on the surface of the second initial work function layer 172 on the sidewall of the second channel pillar 120 and on a portion of the second region II; and using the first sidewall spacers 181 and the second sidewall spacers 182 as a mask, etching the first initial work function layer 162 and the second initial work function layer 172 till the first initial work function layer 162 and the second initial work function layer 172 at the third region III are removed.

For example, in one embodiment, using the first sidewall spacers 181 and the second sidewall spacers 182 as a mask, the first initial work function layer 162 and the second initial work function layer 172 may be etched till the surface of the first dielectric layer 150 is exposed.

In one embodiment, using the first sidewall spacers 181 and the second sidewall spacers 182 as a mask, the first initial work function layer 162 and the second initial work function layer 172 may be etched. Therefore, while removing the first initial work function layer 162 and the second initial work function layer 172 at the third region III, the first initial work function layer 162 on the top surface of the first initial gate dielectric layer 161 and the second initial work function layer 172 on the top surface of the second initial gate dielectric layer 171 may also be removed.

While removing the first initial work function layer 162 on the top surface of the first initial gate dielectric layer 161 and the second initial work function layer 172 on the top surface of the second initial gate dielectric layer 171, the first initial gate dielectric layer 161 on the top surface of the first channel pillar 110 and the second initial gate dielectric layer 171 on the top surface of the second channel pillar 120 may be retained. Therefore, the morphology of the top surfaces of the first channel pillar 110 and the second channel pillar 120 may be protected in the subsequent etching process.

The first initial work function layer 162 may be etched using a process including a dry etching process, a wet etching process, and/or a combination thereof.

In one embodiment, the first initial work function material layer 162 may be etched by a dry etching process. The process parameters of the dry etching process may include gases including SF₆, Cl₂, and CF₄, where the flow range of SF₆ is about 30 standard mL/min to about 300 standard mL/min, the flow range of Cl₂ is about 60 standard mL/min to about 150 standard mL/min, and the flow range of CF₄ is about 10 standard mL/min to about 600 standard mL/min; and further include a pressure range of about 2 mTorr to about 200 mTorr.

The second initial work function layer 172 may be etched using a process including a dry etching process, a wet etching process, and/or a combination thereof.

In one embodiment, the second initial work function material layer 172 may be etched by a dry etching process. The process parameters of the dry etching process may include gases including SF₆ and Cl₂, where the flow range of SF₆ is about 20 standard mL/min to about 300 standard mL/min, and the flow range of Cl₂ is about 60 standard mL/min to about 150 standard mL/min; and further include a pressure range of about 2 mTorr to about 200 mTorr.

In one embodiment, forming the first sidewall spacer 181 and the second sidewall spacer 182 may include depositing a sidewall spacer material layer (not shown) on the surface of the first initial work function layer 162 and the second initial work function layer 163; and etching back the sidewall spacer material layer till the surfaces of the first initial work function layer 162 and the second initial work function layer 172 are exposed.

In one embodiment, the material of the sidewall spacer material layer may be silicon nitride, that is, the material of each of the first sidewall spacer 181 and the second sidewall spacer 182 may be silicon nitride.

In other embodiments, the sidewall spacer material layer may be made of a material including silicon oxide, silicon oxynitride, silicon oxycarbide, silicon carbonitride, or silicon oxycarbonitride, and/or any other suitable material(s).

In one embodiment, the sidewall spacer material layer may be deposited by a process including a chemical vapor deposition process.

In one embodiment, after removing the first initial work function layer 162 and the second initial work function layer 172 at the third region III, the first sidewall spacer 181 and the second sidewall spacer 182 may be removed.

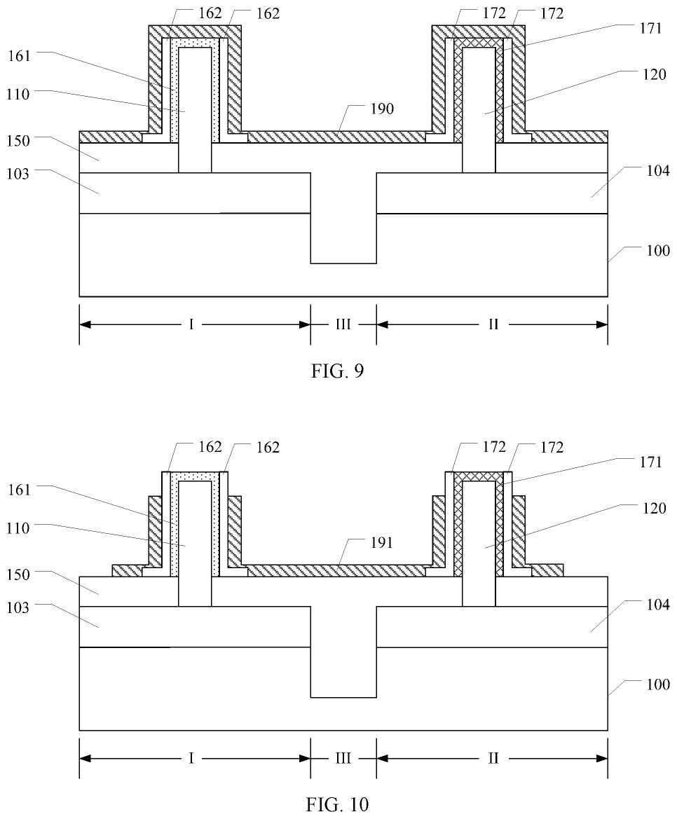

Referring to FIG. 9, after removing the first initial work function layer 162 and the second initial work function layer 172 at the third region III, a gate electrode material layer 190 may be formed on the first channel pillar 110, the second channel pillar 120, and the substrate 100.

The gate electrode material layer 190 may be used to subsequently form the gate electrode layer.

In one embodiment, the gate electrode material layer 190 may be made of a metal material including one or a combination of tungsten, cobalt, copper, nickel, titanium, and titanium nitride.

In one embodiment, the gate electrode material layer may be formed by a process including an atomic layer deposition process or a chemical vapor deposition process.

Referring to FIG. 10, the gate electrode material layer 190 on the top of the first channel pillar 110 and the top of the second channel pillar 120 may be etched to form a gate electrode layer 191.

In one embodiment, not only the gate electrode material layer 190 on the top of the first channel pillar 110 and the top of the second channel pillar 120 may be etched, but also the gate electrode material layer 190 on a portion of the sidewall of the first channel pillar 110, a portion of the sidewall of the second channel pillar 120, on the substrate 100 at a portion of the first region I and at a portion of the second region II may be etched.

In another embodiment, the gate electrode material layer on the sidewalls of the first channel pillar 110 and the second channel pillar 120 may not be etched.

The gate electrode material layer 190 may be etched by a process including a dry etching process or a wet etching process.

In one embodiment, the gate electrode material layer 190 may be etched using a dry etching process.

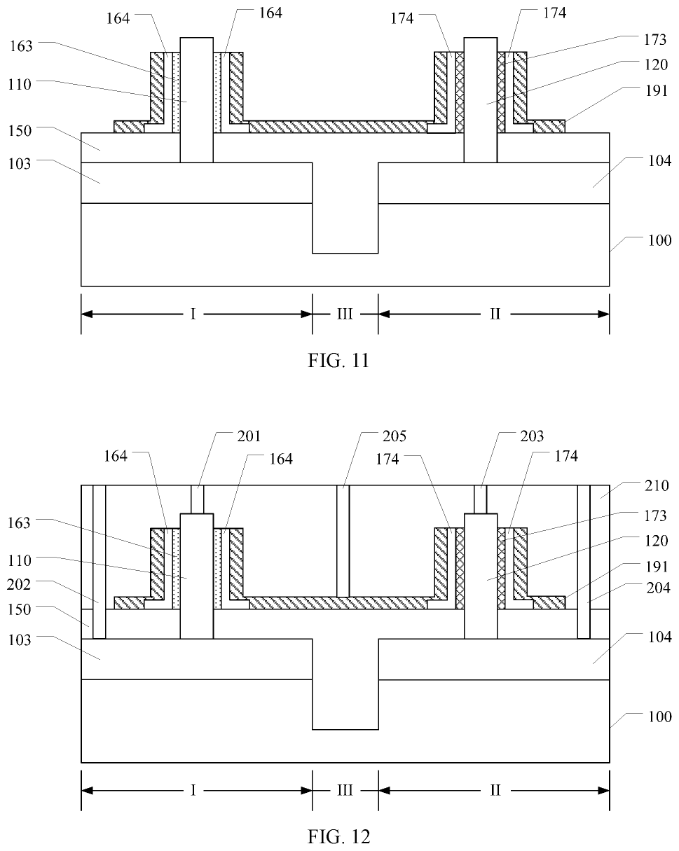

Referring to FIG. 11, after etching the gate electrode material layer 190 on the top of the first channel pillar 110 and the top of the second channel pillar 120, the exposed first initial gate dielectric layer 161 and the second initial gate dielectric layer 171 may be etched to form a first gate dielectric layer 163 and a second gate dielectric layer 173.

The first initial gate dielectric layer 161 and the second initial gate dielectric layer 171 may be etched using a process including a dry etching process, a wet etching process, or a combination thereof.

In one embodiment, the first initial gate dielectric layer 161 and the second initial gate dielectric layer 171 may be etched using a dry etching process.

In one embodiment, after etching the gate electrode material layer 190 on the top of the first channel pillar 110 and the top of the second channel pillar 120 and before etching the exposed first initial gate dielectric layer 161 and the exposed second initial gate dielectric layer 171, the exposed first initial work function layer 162 and the exposed second initial work function layer 172 may be etched to form a first work function layer 164 and a second work function layer 174 (e.g., in S803 and S804 of FIG. 13).

The first initial work function layer 162 and the second initial work function layer 172 may be etched by a process including a dry etching process or a wet etching process.

In one embodiment, the first initial work function layer 162 and the second initial work function layer 172 may be etched by a dry etching process.

Referring to FIG. 12, after forming the first gate dielectric layer 163 and the second gate dielectric layer 173, a first plug 201 may be formed on the top surface of the first channel pillar 110, a second plug 202 may be formed on the surface of the first source/drain doped layer 101 at the first region I, a third plug 203 may be formed on the top surface of the second channel pillar 120, a fourth plug 204 may be formed on the surface of the second source/drain doped layer 102 at the second region II, and a fifth plug 205 may be formed on the surface of the gate electrode layer 191 at the third region III. In addition, a second dielectric layer 210 may be formed on the surface of the first dielectric layer 150 to surround the gate electrode layer 191, the first channel pillar 110, the second channel pillar 120, the first plug 201, the second plug 202, the third plug 203, the fourth plug 204, and the fifth plug 205.

In one embodiment, the first plug 201, the second plug 202, the third plug 203, the fourth plug 204, and the fifth plug 205 may each be made of one or a combination of metal materials, such as tungsten, cobalt, copper, one or more of nickel, titanium and titanium nitride.

In one embodiment, the second dielectric layer 210 may be made of silicon oxide.

Correspondingly, the embodiments of the present disclosure provide a semiconductor structure. Referring to FIG. 12, the semiconductor structure may include the substrate 100, where the substrate 100 includes the first region I, the second region II, and the third region III between the first region I and the second region II; the first channel pillar 110 on the surface of the first region I and the second channel pillar 120 on the surface of the second region II; the first work function layer 164 on the first region I of the substrate 100 and on the sidewall surface of the first channel pillar 110; and the second work function layer 174 on the second region II of the substrate 100 and the sidewall surface of the second channel pillar 120.

The substrate 100 includes the first region I, the second region II, and the third region III between the first region I and the second region II; the first work function layer 164 is on the sidewall surface of the first channel pillar 110 and the first region I, and the second work function layer 174 is on the sidewall surface of the second channel pillar 120 and the second region II, that is, the first work function layer 164 and the second work function layer 174 are separated from each other. Therefore, the ion diffusion between the first work function layer 164 and the second work function layer 174 may be reduced, thereby reducing the ion concentration change in the first work function layer 164 and the second work function layer 174. Furthermore, the change of the turn-on voltage of the semiconductor device may be reduced, and the deviation of the electrical performance of the semiconductor device may be reduced, such that the stability of the electrical performance of the semiconductor device may be improved, thereby improving the performance of the semiconductor device.

In another embodiment, along the direction perpendicular to the surface of the substrate, the second work function layer may include the fourth region, and the fifth isolation region on the fourth region, and a portion of the first work function layer may be also on the surface of the second work function layer.

On the one hand, due to the existence of the fifth isolation region, even if the portion of the first work function layer is also on the surface of the second work function layer, the ions of the first work function layer or the second work function layer may diffuse between such two layers through the top surface of the second work function layer using the fifth isolation region, thereby reducing the ion concentration change in the first work function layer and the second work function layer. The change of the turn-on voltage of the semiconductor device may be reduced, that is, the deviation of the electrical performance of the semiconductor device may be reduced, thereby improving the stability of the electrical performance of the semiconductor device and the performance of the semiconductor device. On the other hand, along the direction perpendicular to the surface of the second work function layer, only a portion of the second work function layer has the fifth isolation region, and the second work function layer adjacent to the second channel pillar is not modified. Therefore, the fifth isolation region may have relatively small influence on the electrical performance, such as the turn-on voltage, of the second work function layer.

The substrate 100 may be made of a semiconductor material.

In one embodiment, the substrate 100 may be made of silicon. In other embodiments, the substrate may be made of a material including silicon carbide, silicon germanium, a multi-element semiconductor material composed of group III-V elements, silicon-on-insulator (SOI), germanium-on-insulator, and/or any combination thereof. The multi-element semiconductor material composed of group III-V elements may include InP, GaAs, GaP, InAs, InSb, InGaAs, InGaAsP, and/or a combination thereof.

In one embodiment, the substrate 100 includes the first source/drain doped layer 103 in the first region I and the second source/drain doped layer 104 in the second region II.

The first source/drain doped layer 103 may contain first ions, the second source/drain doped layer 104 may contain second ions, and the conductivity types of the first ions and the second ions may be different.

For example, in one embodiment, the surface of the substrate 100 at the first region I may include the surface of the first source/drain doped layer 103, and the surface of the substrate 100 at the second region II may include the surface of the second source/drain doped layer 104.

In one embodiment, the first ions may be N-type, and the second ions may be P-type.

In other embodiments, the first ions may be P-type, and the second ions may be N-type.

The N-type ions may include phosphorus ions, arsenic ions, or antimony ions, and the P-type ions may include boron ions, BF²⁻ ions, or indium ions.

In one embodiment, the first work function layer 164 may be made of titanium aluminide.

In another embodiment, the first work function layer may be made of a material including titanium nitride, tantalum nitride, and/or any other suitable material(s).

In one embodiment, the second work function layer 174 may be made of a material including titanium nitride, tantalum nitride, and/or any other suitable material(s).

In another embodiment, the second work function layer may be made of titanium aluminide.

In one embodiment, the substrate 100 at the third region III may have the first opening 140 (shown in FIG. 3), and the surface of the substrate 100 may expose the first opening 140.

In one embodiment, the semiconductor structure may further include the first dielectric layer 150 in the first opening 140 and on the surface of the substrate 100.

In one embodiment, the first dielectric layer 150 may be made of silicon oxide.

In one embodiment, the semiconductor structure may further include the first gate dielectric layer 163 between the sidewall surface of the first channel pillar 110 and the first work function layer 164, the second gate dielectric layer 173 between the sidewall surface of the second channel pillar 120 and the second work function layer 174, and the gate electrode layer 191 on the surface of the first work function layer 164, the surface of the second work function layer 174, and the third region III.

In one embodiment, the material of the first gate dielectric layer 163 may include a combination of silicon oxide and a high dielectric constant material.

In other embodiments, the first gate dielectric layer 163 may be made of silicon oxide.

In one embodiment, the material of the second gate dielectric layer 173 may include a combination of silicon oxide and a high dielectric constant material.

In other embodiments, the second gate dielectric layer 173 may be made of silicon oxide.

It should be noted that the high dielectric constant material may be a material with a dielectric constant greater than 3.9.

The high dielectric constant material may include titanium oxide, aluminum oxide, hafnium oxide, tantalum oxide, lanthanum oxide, and/or any other suitable material(s).

In one embodiment, the high dielectric constant material may include hafnium oxide.

In one embodiment, the gate electrode layer 191 may be made of a metal material including one or a combination of tungsten, cobalt, copper, nickel, titanium, and titanium nitride.

In one embodiment, the semiconductor structure may further include:

the first plug 201 on the top surface of the first channel pillar 110; the second plug 202 on the surface of the first source/drain doped layer 101 at the first region I; the third plug 201 on the top surface of the second channel pillar 120; the fourth plug 204 on the surface of the second source/drain doped layer 102 at the second region II; the fifth plug 205 on the surface of the gate electrode layer 191 at the third region; and the second dielectric layer 210 on the surface of the first dielectric layer 150 to surround the gate electrode layer 191, the first channel pillar 110, the second channel pillar 120, the first plug 201, the second plug 202, the third plug 203, the fourth plug 204, and the fifth plug 205.

In one embodiment, the first plug 201, the second plug 202, the third plug 203, the fourth plug 204, and the fifth plug 205 may each be made of one or a combination of metal materials, such as tungsten, cobalt, copper, one or more of nickel, titanium and titanium nitride.

In one embodiment, the second dielectric layer 210 may be made of silicon oxide.

Although the present disclosure has been disclosed above, the present disclosure is not limited thereto. Any changes and modifications may be made by those skilled in the art without departing from the spirit and scope of the disclosure, and the scope of the disclosure should be determined by the scope defined by the appended claims.

What is claimed is:

1. A semiconductor structure, comprising:
a substrate, including a first region, a second region, and a third region between the first region and the second region;
a first channel pillar on the first region and a second channel pillar on the second region;
a first work function layer on the first region of the substrate and on a sidewall surface of the first channel pillar; and
a second work function layer on the second region of the substrate and on a sidewall surface of the second channel pillar.

2. The structure according to claim 1, further including:
a first gate dielectric layer between the sidewall surface of the first channel pillar and the first work function layer,
a second gate dielectric layer between the sidewall surface of the second channel pillar and the second work function layer, and
a gate electrode layer on the first work function layer, the second work function layer, and the third region of the substrate.

3. The structure according to claim 1, wherein:
the substrate includes a first opening at the third region and exposed by a surface of the substrate; and
a first dielectric layer is formed in the first opening and on the surface of the substrate.

4. The structure according to claim 1, wherein:
the first work function layer is made of a material including titanium aluminide.

5. The structure according to claim 1, wherein:
the second work function layer is made of a material including titanium nitride, tantalum nitride, or a combination thereof.

6. The structure according to claim 2, wherein:
a material of the first gate dielectric layer includes a combination of silicon oxide and a high dielectric constant material; and
a material of the second gate dielectric layer includes a combination of silicon oxide and a high dielectric constant material.

7. The structure according to claim 1, wherein:
the substrate includes a first source/drain doped layer containing first ions and a second source/drain doped layer containing second ions; and conductivity types of the first ions and the second ions are different.

8. A method for fabricating a semiconductor structure, comprising:
providing a substrate, including a first region, a second region, and a third region between the first region and the second region;
forming a first channel pillar on the first region and a second channel pillar on the second region;
forming a first work function layer on the first region of the substrate and on a sidewall surface of the first channel pillar; and
forming a second work function layer on the second region of the substrate and on a sidewall surface of the second channel pillar.

9. The method according to claim 8, further including:
forming a first gate dielectric layer between the sidewall surface of the first channel pillar and the first work function layer,
forming a second gate dielectric layer between the sidewall surface of the second channel pillar and the second work function layer, and
forming a gate electrode layer on the first work function layer, the second work function layer, and the third region of the substrate.

10. The method according to claim 9, wherein:
forming the first gate dielectric layer and the first work function layer includes:
forming a first initial gate dielectric layer on the first channel pillar, and
forming a first initial work function layer on the first initial gate dielectric layer, on the first region of the substrate, and on a portion of the third region; and
forming the second gate dielectric layer and the second work function layer includes:
forming a second initial gate dielectric layer on the second channel pillar; and
forming a second initial work function layer on the second initial gate dielectric layer, on the second region of the substrate, and on a portion of the third region.

11. The method according to claim 10, wherein forming the second initial work function layer includes:
forming a second initial work function material layer on the substrate, the first initial gate dielectric layer, and the second initial gate dielectric layer;
forming a second patterned layer on the second initial work function material layer at the second region and the portion of the third region; and
using the second patterned layer as a mask, etching the second initial work function material layer.

12. The method according to claim 11, wherein forming the first initial work function layer includes:
forming a first initial work function material layer on the substrate, the first initial gate dielectric layer, and the second initial work function layer.

13. The method according to claim 12, wherein forming the first initial work function layer further includes:
forming a first patterned layer on the first initial work function material layer at the first region and the portion of the third region; and
using the first patterned layer as a mask, etching the first initial work function material layer till a surface of the second initial work function layer is exposed.

14. The method according to claim 10, wherein forming the first work function layer and the second work function layer further includes:
removing the first initial work function layer and the second initial work function layer on the third region.

15. The method according to claim 14, wherein removing the first initial work function layer and the second initial work function layer on the third region of the substrate includes:
forming a first sidewall spacer on the first initial work function layer on the sidewall surface of the first channel pillar and on a portion of the first region of the substrate;
forming a second sidewall spacer on the second initial work function layer on the sidewall surface of the second channel pillar and on a portion of the second region of the substrate; and
using the first sidewall spacer and the second sidewall spacer as a mask, etching the first initial work function layer and the second initial work function layer till the first initial work function layer and the second initial work function layer on the third region are removed.

16. The method according to claim 15, wherein forming the first sidewall spacer and the second sidewall spacer includes:
depositing a sidewall spacer material layer on the first initial work function layer and the second initial work function layer; and
etching back the sidewall spacer material layer till surfaces of the first initial work function layer and the second initial work function layer are exposed.

17. The method according to claim 14, wherein forming the gate electrode layer includes:
after removing the first initial work function layer and the second initial work function layer on the third region, forming a gate electrode material layer on the first channel pillar, the second channel pillar, and the substrate; and
etching the gate electrode material layer on tops of the first channel pillar and the second channel pillar to form the gate electrode layer.

18. The method according to claim 17, wherein forming the first gate dielectric layer and the second gate dielectric layer includes:
after etching the gate electrode material layer on the tops of the first channel pillar and the second channel pillar, etching an exposed first initial gate dielectric layer and an exposed second initial gate dielectric layer.

19. The method according to claim 18, wherein after forming the first channel pillar and the second channel pillar and before forming the first work function layer and the second work function, the method further includes:
forming a first opening at the third region of the substrate and exposed by a surface of the substrate; and
forming a first dielectric layer in the first opening and on the surface of the substrate.
